(19) United States
(12) Patent Application Publication
(10) Pub. No.: US 2013/0258617 A1
(43) Pub. Date: Oct. 3, 2013

(54) DISPLAY DEVICE

(71) Applicant: KABUSHIKI KAISHA TOSHIBA, Tokyo (JP)

(72) Inventor: Shigeo INOUE, Saitama (JP)

(73) Assignee: KABUSHIKI KAISHA TOSHIBA, Tokyo (JP)

(21) Appl. No.: 13/672,083

(22) Filed: Nov. 8, 2012

(30) Foreign Application Priority Data
Mar. 30, 2012 (JP) 2012-082472

(51) Int. Cl. H05K 7/02

(52) U.S. Cl. CPC H05K 7/02
USPC 361/752

(57) ABSTRACT

According to one embodiment, a display device includes: a casing comprising an opening; a display, at least a part of the display being housed in the casing; a circuit board configured to be housed in the casing and comprising a first side and a second side; a plurality of connector terminals on each of the first side and the second side of the circuit board and exposed through the opening; a first covering configured to be supported on the circuit board, and facing the first side to cover the opening; and a second covering configured to be supported on the circuit board, and facing the second side to cover the opening.

### CROSS-REFERENCE TO RELATED APPLICATIONS

This application is based upon and claims the benefit of priority from Japanese Patent Application No. 2012-082472, filed on Mar. 30, 2012, the entire contents of which are incorporated herein by reference.

### FIELD

Embodiments described herein relate generally to a display device.

### BACKGROUND

Conventionally, there has been known a display device in which connectors are exposed from openings provided on the back surface of the casing of the display device.

It is desired that time and efforts for manufacturing this kind of display device be reduced even when equipped with a plurality of connectors.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary front view illustrating one example of a display device according to an embodiment;

FIG. 2 is an exemplary rear view illustrating one example of the display device in the embodiment;

FIG. 3 is an exemplary perspective view illustrating one example of a part of the rear surface of the display device in the embodiment;

FIG. 4 is an exemplary rear view illustrating one example of the display device in the embodiment in a state where a back cover is removed from the display device;

FIG. 5 is an exemplary plan view illustrating one example of a board and side covers of the display device in the embodiment;

FIG. 6 is an exemplary perspective view illustrating one example of the board and the side covers of the display device in the embodiment;

FIG. 7 is an exemplary perspective view illustrating one example of a first side cover of the display device in the embodiment;

FIG. 8 is an exemplary perspective view illustrating one example of the first side cover of the display device in the embodiment, the perspective view illustrating the first side cover as viewed from an angle different from that in FIG. 7;

FIG. 9 is an exemplary perspective view illustrating one example of a second side cover of the display device in the embodiment;

FIG. 10 is an exemplary perspective view illustrating one example of the second side cover of the display device in the embodiment, the perspective view illustrating the second side cover as viewed from an angle different from that in FIG. 9;

FIG. 11 is an exemplary plan view (partially cross-sectional view) illustrating one example of a part of the board and the first side cover of the display device in the embodiment;

FIG. 12 is an exemplary plan view (partially cross-sectional view) illustrating one example of a part of the board and the second side cover of the display device in the embodiment;

FIG. 13 is an exemplary plan view (partially cross-sectional view) illustrating one example of a part of the board, the first side cover, and the second side cover of the display device in the embodiment;

FIG. 14 is an exemplary plan view (partially cross-sectional view) illustrating one example of a part of the first side cover and the second side cover of the display device in the embodiment;

FIG. 15 is an exemplary perspective view illustrating one example of apart of a wall portion of a casing, the first side cover, and the second side cover of the display device in the embodiment;

FIGS. 16A to 16C are exemplary plan views illustrating one example of procedures for mounting the side covers on the board of the display device in the embodiment, FIG. 16A illustrating the board only, FIG. 16B illustrating the first side cover attached to the board, and FIG. 16C illustrating the first side cover and the second side cover both attached to the board; and

FIG. 17 is an exemplary plan view (partially cross-sectional view) illustrating one example of a part of the first side cover and the second side cover of the display device according to a modification of the embodiment.

### DETAILED DESCRIPTION

In general, according to one embodiment, a display device comprises: a casing comprising an opening; a display, at least a part of the display being housed in the casing; a circuit board configured to be housed in the casing and comprising a first side and a second side; a plurality of connector terminals on each of the first side and the second side of the circuit board and exposed through the opening; a first covering configured to be supported on the circuit board, and facing the first side to cover the opening; and a second covering configured to be supported on the circuit board, and facing the second side to cover the opening.

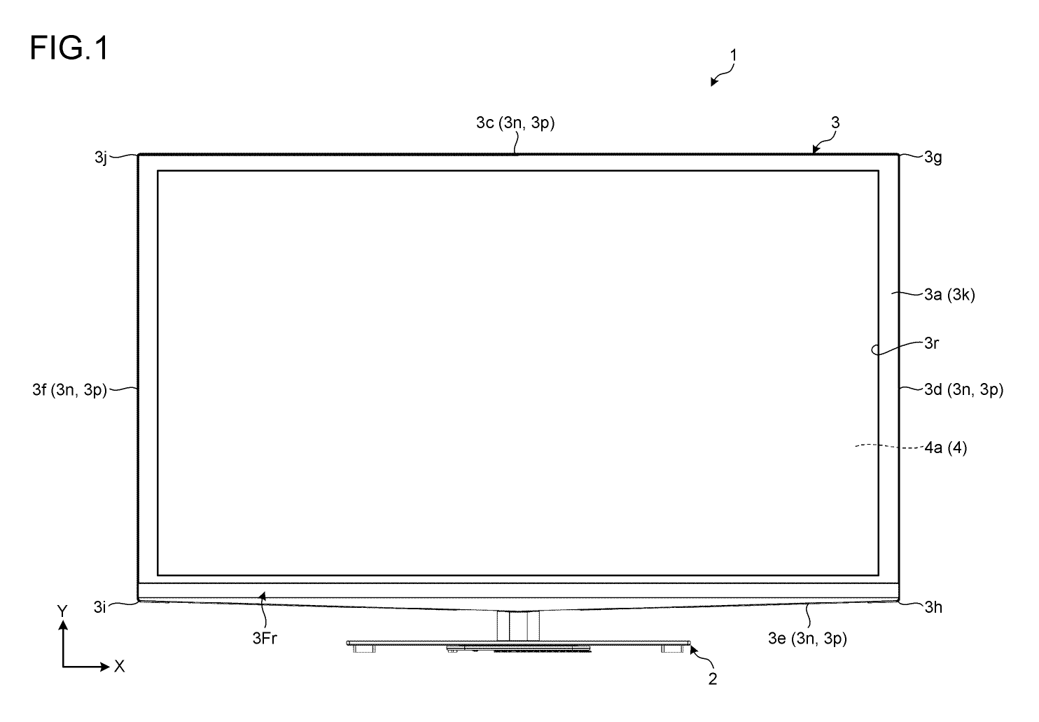

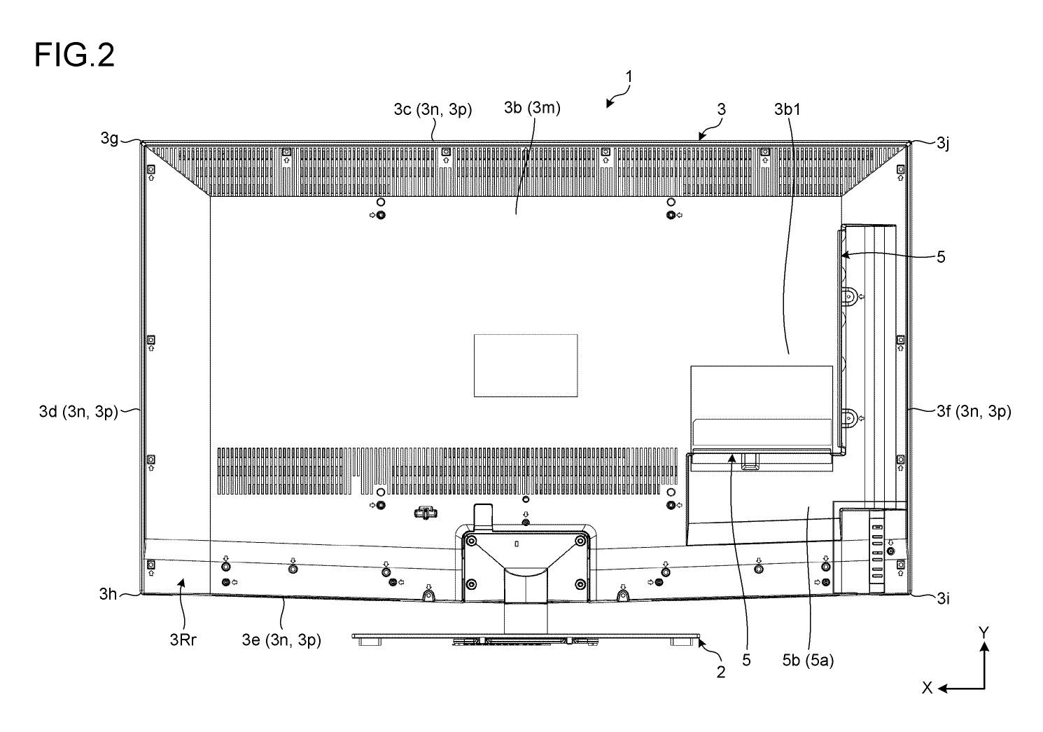

Hereinafter, for the sake of convenience, explanations are made in conjunction with drawings including directions (the X direction, the Y direction, the Z direction) indicated thereon. The X direction indicates the longitudinal direction (the right direction in FIG. 1 and the left direction in FIG. 2) of a casing 3 as viewed in a front view with respect to a display screen 4a. The Y direction indicates the transverse direction (the upward direction in FIGS. 1 and 2) of the casing 3 as viewed in a front view with respect to the display screen 4a. The Z direction indicates the thickness direction of the casing 3 as viewed in a front view with respect to the display screen 4a. The X direction, the Y direction, and the Z direction are orthogonal to one another.

Furthermore, in the following embodiments, although a display device constituted as a television receiver is exemplified, a display device according to the present embodiment is not limited thereto. The display device in the present embodiment can be constituted, for example, as a video display device, a monitor device or the like, or various kinds of electronic devices other than the television receiver.

In the present embodiment, as one example illustrated in FIGS. 1 and 2, a television receiver 1 (the display device) comprises a support 2 (a support base, abase, a stand) and the casing 3. To be more specific, the support 2 is mounted on a mounting base (a mounting face, not illustrated in the drawings) such as a desk, a shelf, or a base, and supports the casing 3 in an erected manner. The support 2 may support the casing 3 in a fixed manner or in a movable manner (a rotatable manner, a slidable manner). Examples of the type of moving (rotating) the casing 3 with respect to the support 2 include a tilting type, swiveling type, and a pivoting type.

Furthermore, in the present embodiment, as can be understood from one example illustrated in FIGS. 1 and 2, the casing 3 has an external appearance of a quadrangular shape (a rectangular shape as one example in the present embodiment) as viewed in a front view and a rear view. As illustrated in FIG. 2, the casing 3 is constituted of a rectangular parallelepiped-shaped body formed thinly in the anterioposterior direction (the thickness direction of the casing 3, the Z direction) . The casing 3 comprises a face 3a (a front face, an anterior face, a surface portion) and a face 3b (a rear face, a back face, a surface portion) opposite to the face 3a. The face 3a and the face 3b are provided substantially parallel to each other (parallel to each other, as one example in the present embodiment) . As illustrated in FIG. 1, the casing 3 comprises four end portions 3c to 3f (side portions, edge portions) and four corner portions 3g to 3j (distal end portions, curbed portions, end portions) as viewed in a front view. The end portion 3c or 3e is one example of a long side portion. The end portion 3d or 3f is one example of a short side portion. The casing 3 functions, as one example, as a housing that houses parts (not illustrated in the drawings) and can also function as a support that supports heavy loads (a display unit 4, parts, and the like) .

Furthermore, the casing 3 comprises a wall portion 3k (a part, a plate, a frame, a front wall portion, a face wall portion, a top wall portion) having the face 3a, and a wall portion 3m (a part, a plate, a rear wall portion, a back wall portion, a bottom wall portion) having the face 3b. The wall portions 3k and 3m are formed in a quadrangular shape (rectangular shape as one example in the present embodiment) . The wall portion 3k is formed in a frame shape and the wall portion 3m is formed in a plate shape. The casing 3 comprises four wall portions 3n (parts, plates, side wall portions, end wall portions, erected wall portions, extending portions) having faces 3p (side faces, peripheral faces, extending faces) extending between the wall portion 3k and the wall portion 3m. The wall portion 3k is provided with an opening 3r having a quadrangular shape.

In addition, the casing 3 is constituted of a plurality of parts (separated bodies, members) combined with each other. The casing 3 comprises, as one example, a first member 3Fr (a first part, a front side member, a cover, a bezel, a frame, a mask) comprising as least the wall portion 3k and a second member 3Rr (a second part, a back side member, a base, a bottom, a plate, a cover) comprising at least the wall portion 3m. The wall portion 3n is constituted, as one example in the present embodiment, as a part of the second member 3Rr. Here, the casing 3 can be provided with a third member (a third portion, an intermediate member, an inner, a middle frame, a middle plate, not illustrated in the drawings) in addition to the first member 3Fr and the second member 3Rr. In that case, a part of the third member can constitute a part of the wall portions 3k, 3m, and 3n. The first member 3Fr, the second member 3Rr, the third member, or the like can be made of a metallic material, a synthetic-resin material, or the like.

In the present embodiment, as one example, the casing 3 houses the display unit 4 (a display portion, a display, a panel, a display part) therein. The display screen 4a positioned on a face-3a side of the display unit 4 is exposed frontward (outwardly) from the casing 3 byway of the opening 3r. Users can visually observe the display screen 4a from the front side of the casing 3 through the opening 3r. The display unit 4 has an external appearance of a quadrangular shape (a rectangular shape, as one example in the present embodiment) as viewed in a front view. The display unit 4 is constituted of a rectangular parallelepiped-shaped body formed thinly in the anterioposterior direction. The display unit 4 is, for example, a liquid crystal display (LCD), an organic electro-luminescent display (GELD), or a plasma display panel (PDP).

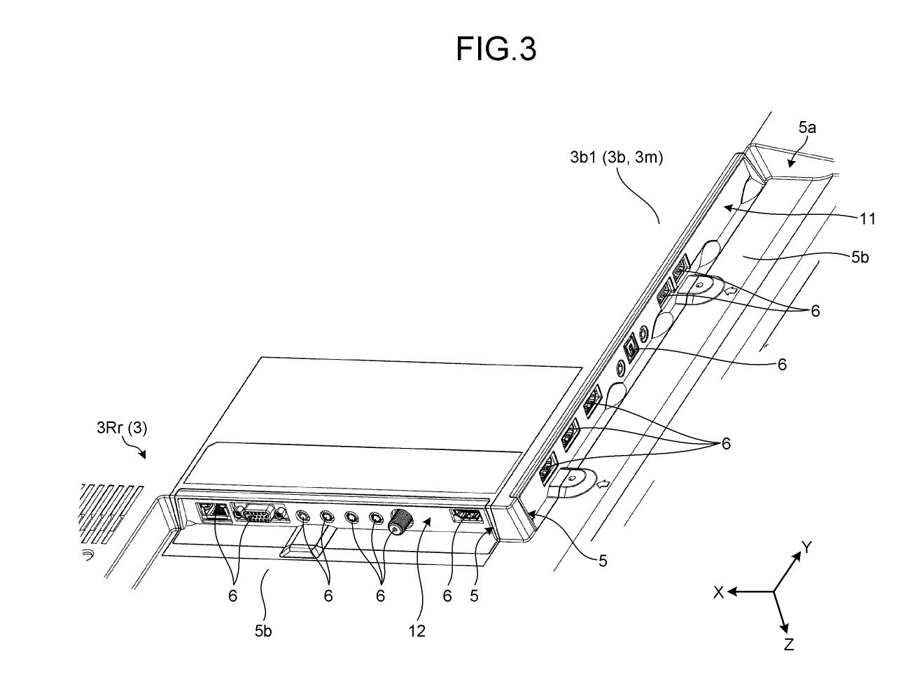

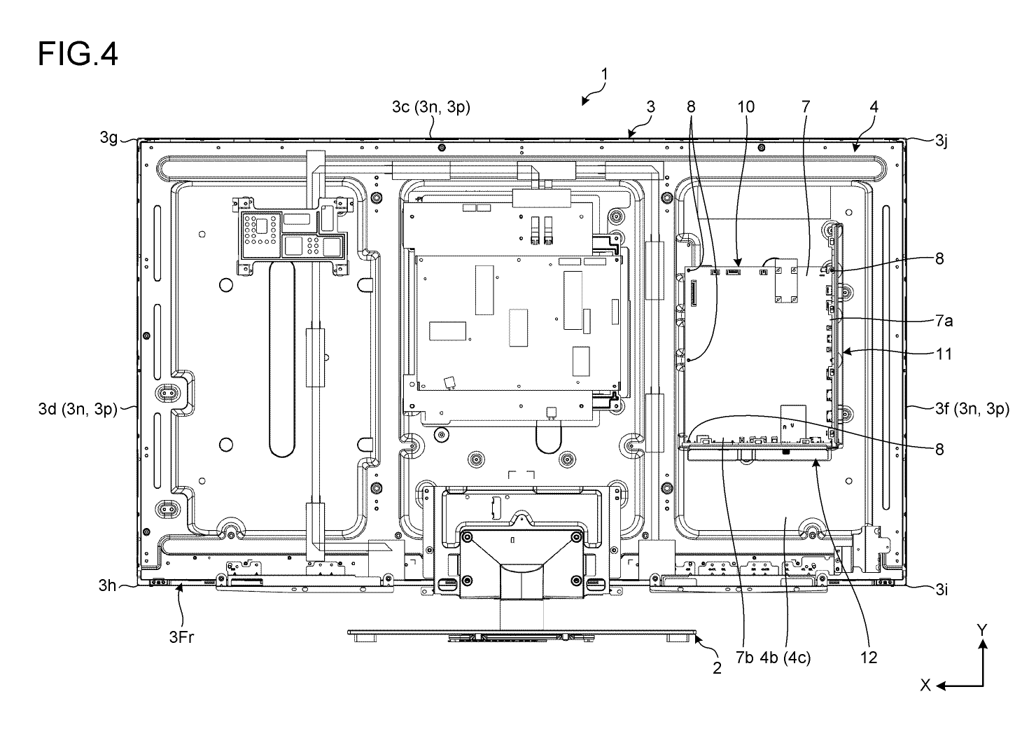

In the present embodiment, as one example illustrated in FIGS. 2 and 3, the wall portion 3m (the second member 3Rr) constituting the face 3b of the casing 3 is provided with an L-shaped recessed portion 5a extending from a right-side region toward a lower-side region in FIG. 2. As illustrated in FIG. 3, slit-like openings 5 that open in the direction along a bottom surface 5b (the face 3b) (in the lateral or downward direction in the present embodiment) are provided between the bottom surface 5b of the recessed portion 5a and a top surface 3b1 (the wall portion 3m) that is a general surface of the face 3b, the bottom surface 5b and the top surface 3b1 constituting a step. A plurality of connector terminals 6 are exposed from the openings 5. As can be clearly understood from FIGS. 2 and 4, the second member 3Rr covers a rear face 4b of the display unit 4. The opening 5 extends over the bottom surface 5b. In this manner, the opening 5 extends over the bottom surface 5b thus suppressing the interference of the second member 3Rr with the connector terminals 6 when the second member 3Rr is mounted on the rear face 4b of the display unit 4.

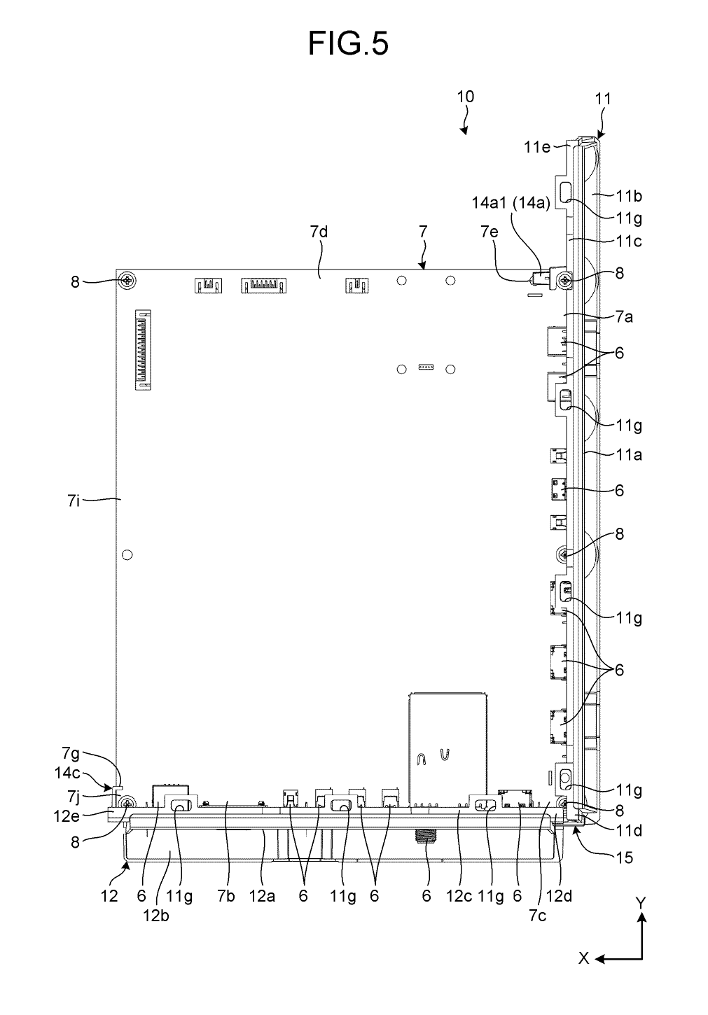

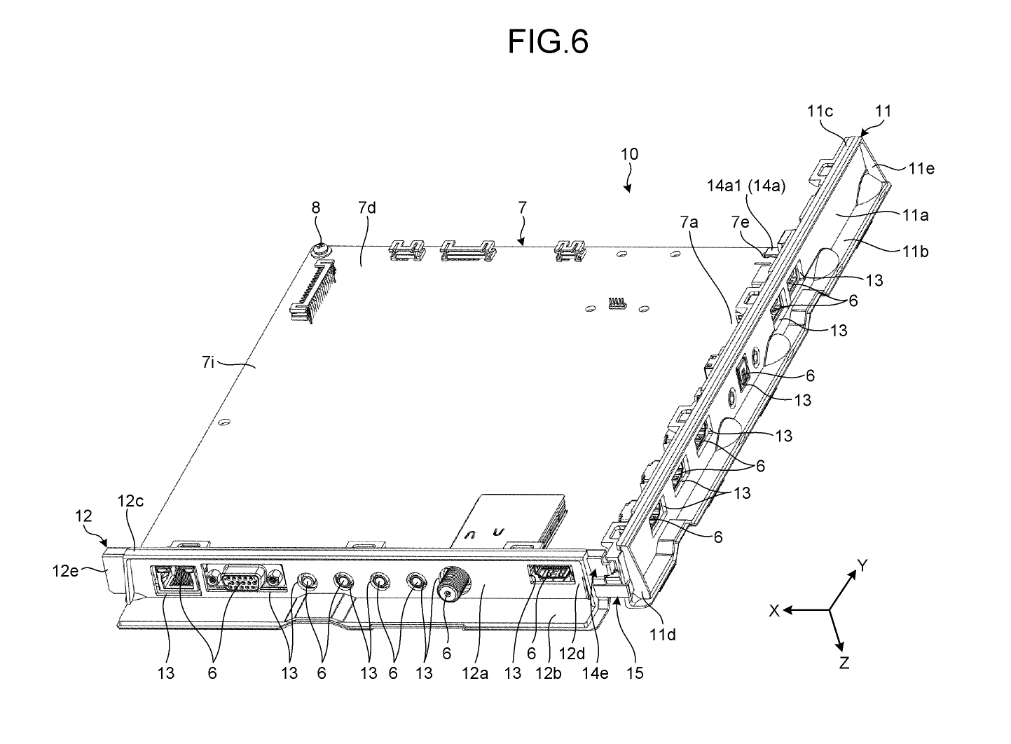

Furthermore, as illustrated in FIG. 4, on a rear wall 4c that constitutes the rear face 4b of the display unit 4, a circuit board 7 is fastened by screws 8 or the like serving as fasteners. In the present embodiment, as illustrated in FIGS. 5 and 6, in the vicinity of a right side 7a (a side portion, a first side portion or a second side portion) of the circuit board 7 positioned at the right side in FIG. 5 and a bottom side 7b (a side portion, a second side portion or a first side portion) adjacent to the right side 7a by way of a corner portion 7c, the plurality of connector terminals 6 are mounted along the right side 7a and the bottom side 7b. Examples of the connector terminal 6 include a card socket, a universal serial bus (USB) terminal, a socket for a local area network (LAN) cable, an RCA terminal, a D terminal, an S terminal, a DV terminal, a radio frequency (RF) terminal, a SCART terminal, a serial digital interface (SDI) terminal, and a pin terminal for audios. The connector terminals 6 are exposed from the opening 5 provided in the second member 3Rr to the outside of the casing 3. Here, on the circuit board 7, wiring patterns (not illustrated in the drawings) comprising conductors are formed and electronic components (not illustrated in the drawings) other than the connector terminals 6 are also mounted.

Here, as illustrated in FIGS. 5 and 6, the connector terminals 6 are arranged in the vicinity of the right side 7a and the bottom side 7b of the circuit board 7. Hence, in the case of the constitution in which the connector terminals 6 are exposed from the slit-like openings 5 without any cover, portions (the right side 7a and the bottom side 7b in the present embodiment) on the periphery of the circuit board 7 are exposed from the openings 5 together with the connector terminals 6, thus deteriorating the appearance thereof. Accordingly, in the present embodiment, as illustrated in FIGS. 5 and 6, side covers 11 and 12 (coverings, a first covering or a second covering) are respectively provided along the right side 7a and the bottom side 7b of the circuit board 7. Due to such a constitution, as illustrated in FIG. 3, the right side 7a and the bottom side 7b of the circuit board 7 are covered with the side covers 11 and 12 thus suppressing the exposure of the right side 7a and the bottom side 7b to the outside by way of the openings 5. The side covers 11 and 12 are covers for partially covering (closing) the openings 5 and, at the same time, for partially covering the right side 7a and the bottom side 7b of the circuit board 7 from the lateral sides of the right side 7a and the bottom side 7b. One of the side covers 11 and 12 is one example of the first covering, and the other side cover is one example of the second covering. In the present embodiment, as one example, an assembly 10 (a board assembly, a subassembly) in which the side covers 11 and 12 are fixed to (supported on) the circuit board 7 is attached to the display unit 4.

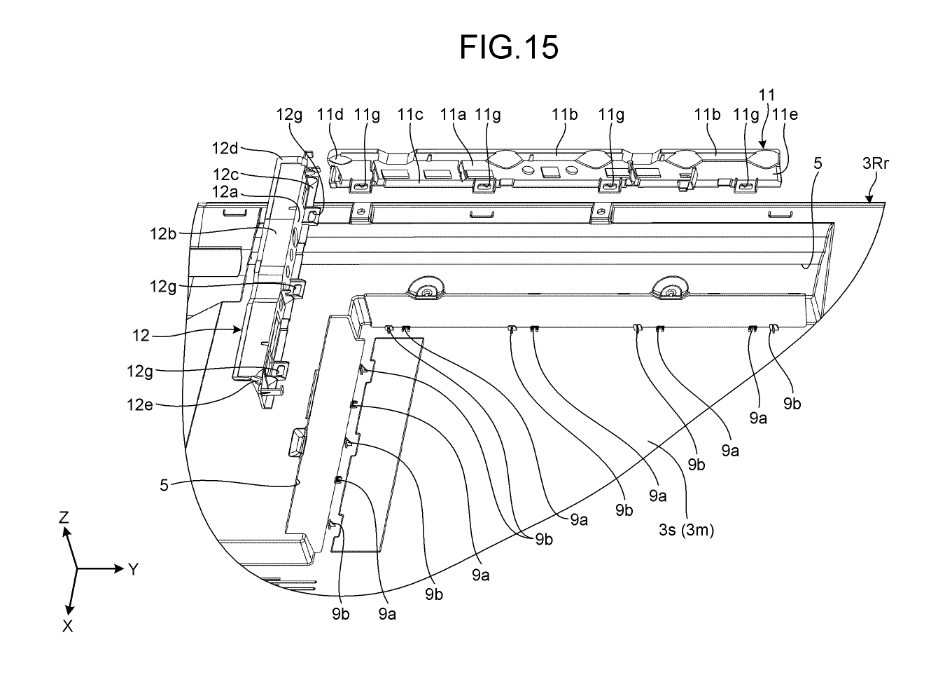

In the present embodiment, as illustrated in FIGS. 5 to 8, the side cover 11 comprises a wall portion 11a (a vertical wall, a standing wall, an erected wall) , a wall portion 11b (a bottom wall, a lower wall, a base wall) , and a wall portion 11c (a top wall, an upper wall, a roof wall). The wall portion 11a faces (opposite to) the right side 7a of the circuit board 7 and extends in a strip shape along the right side 7a in an erected posture on the rear face 4b (see FIG. 4) of the display unit 4 (in a posture in which the wall portion 11a intersects with the rear face 4b). The wall portion 11b is connected to the wall portion 11a on the rear-face-4b side thereof and extends in a strip shape along the rear face 4b. Furthermore, the wall portion 11c is connected to the wall portion 11a on the opposed side of the rear face 4b and extends in a strip shape in parallel with the rear face 4b. The wall portion 11c extends along a face 3s (see FIG. 15) of the wall portion 3m inside the casing 3. That is, in the side cover 11, the wall portion 11a, the wall portion 11b, and the wall portion 11c that are connected to each other constitute an S-shaped (a crank-shaped) cross section.

In the present embodiment, as one example illustrated in FIGS. 5, 6, 9, and 10, the side cover 12 comprises a wall portion 12a (a vertical wall, a standing wall, an erected wall), a wall portion 12b (a bottom wall, a lower wall, a base wall), and a wall portion 12c (a top wall, an upper wall, a roof wall). The wall portion 12a faces (opposite to) the bottom side 7b of the circuit board 7 and extends in a strip shape along the bottom side 7b in an erected posture on the rear face 4b of the display unit 4 (in a posture in which the wall portion 12a intersects with the rear face 4b). The wall portion 12b is connected to the wall portion 12a on the rear-face-4b side thereof and extends in a strip shape along the rear face 4b. Furthermore, the wall portion 12c is connected to the wall portion 12a on the opposed side of the rear face 4b and extends in a strip shape in parallel with the rear face 4b. The wall portion 12c extends along the face 3s of the wall portion 3m inside the casing 3. That is, in the side cover 12, the wall portion 12a, the wall portion 12b, and the wall portion 12c that are connected to each other constitute an S-shaped (a crank-shaped) cross section.

In the present embodiment, as one example illustrated in FIGS . 7 to 10, the wall portion 11a and the wall portion 12a serving as the vertical walls are provided with openings 13 (second openings) for exposing the connector terminals 6. The opening 13 can be provided, as one example illustrated in FIG. 6, for each of one or more connector terminals 6.

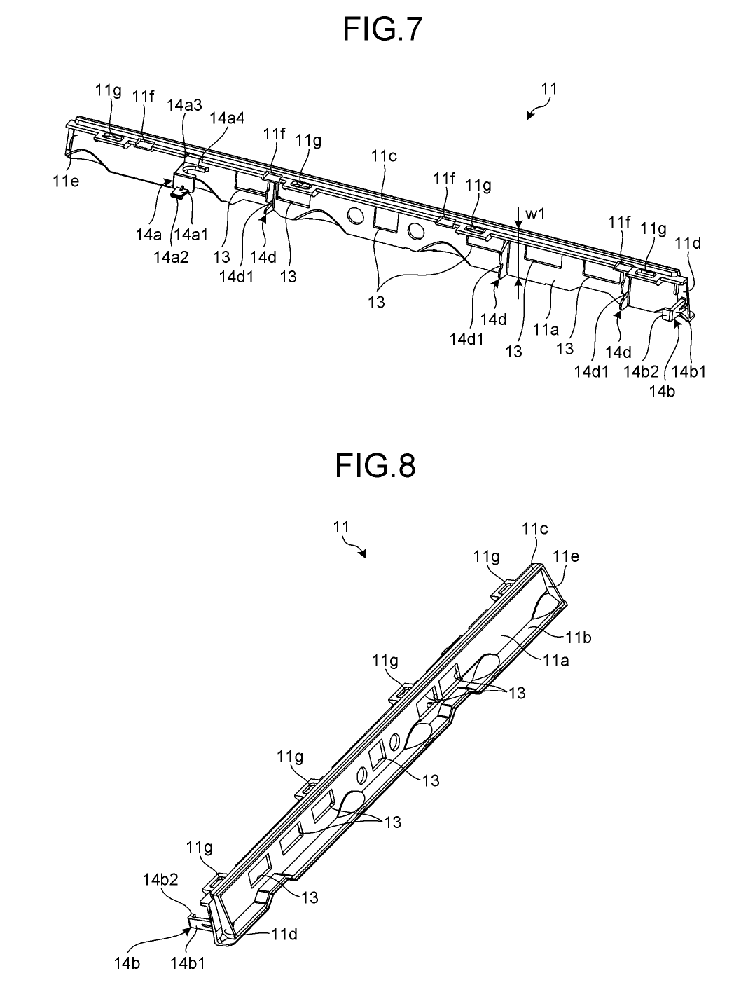

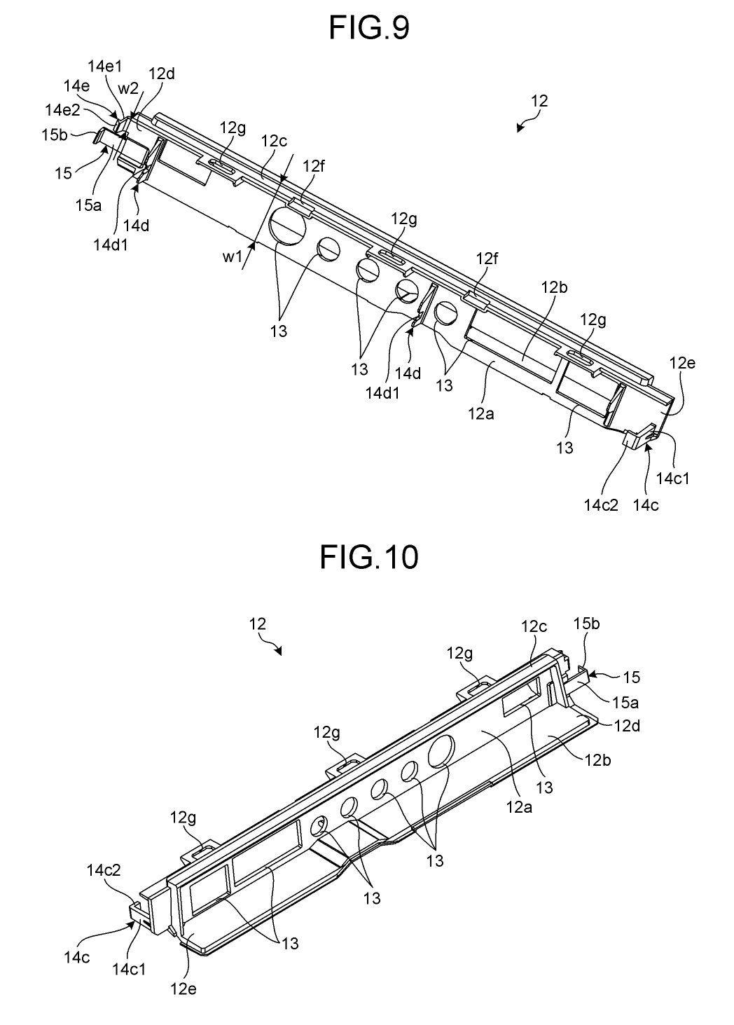

Furthermore, in the present embodiment, as one example illustrated in FIGS. 7 and 9, the side covers 11 and 12 comprise supports 14a to 14d (first supports) supported on the circuit board 7. Out of these supports 14a to 14d, the supports 14a to 14c are engaged with the circuit board 7 thus preventing the side covers 11 and 12 from being separated from the circuit board 7 in the direction in which the side covers 11 and 12 intersect (intersect at right angle) with the right side 7a or the bottom side 7b and in the direction along a face 7d of the circuit board 7.

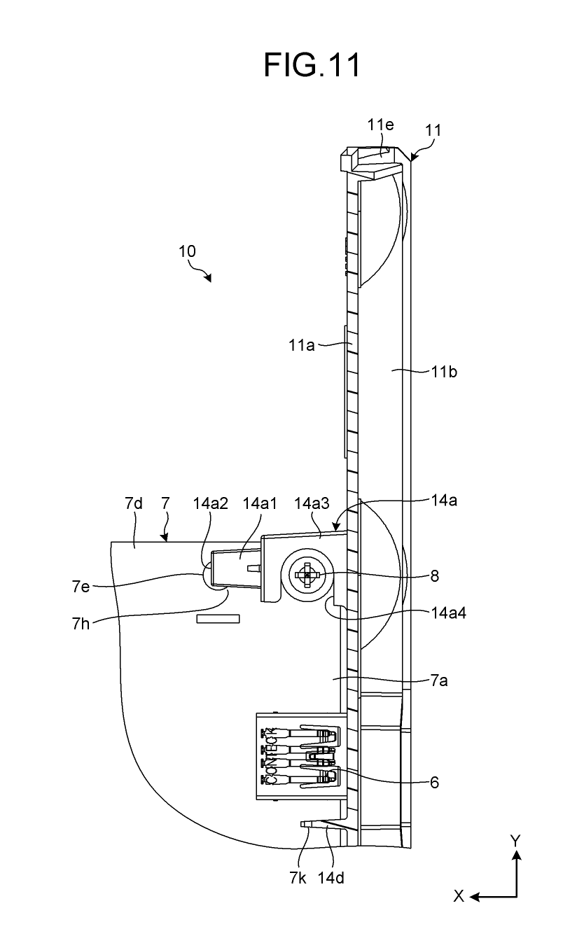

The support 14a is, as illustrated in FIG. 7, arranged at a position closer to an end portion 11e opposite to an end portion 11d than to the end portion 11d in the longitudinal direction of the side cover 11 (the end portion 11d on the side-cover-12 side of the side cover 11), and protrudes from the wall portion 11a in the direction intersecting with (orthogonal to) the wall portion 11a. The support 14a extends, as illustrated in FIG. 11, along the face 7d on the face 7d of the circuit board 7. The support 14a comprises a box-like part 14a3, an arm part 14a1, and a claw part 14a2 . The box-like part 14a3 is formed by connecting three wall parts stereoscopically to increase rigidity thereof thus suppressing the elastic deformation thereof. Furthermore, the box-like part 14a3 is provided with an opening 14a4 (a notch, as one example in the present embodiment). As illustrated in FIG. 11, the opening 14a4 is overlapped with the screw 8 as viewed in the thickness direction of the circuit board 7. That is, when a worker tightens the screw 8 in a state where the support 14a (the side cover 11) is mounted on the circuit board 7, it is possible to fix the circuit board 7 on the rear face 4b (the rear wall 4c) of the display unit 4. The arm part 14a1 (an extending part, a plate-like part, a strip-like part) extends, as illustrated in FIGS. 6 and 11, in a strip-like shape (a plate-like shape) from the box-like part 14a3 along the face 7d in a state where the arm part 14a1 is disposed substantially in contact with the face 7d of the circuit board 7. The claw part 14a2 (a protruding part) protrudes at a distal end portion of the arm part 14a1 in the direction intersecting with (orthogonal to, as one example in the present embodiment) the arm part 14a1 and in the thickness direction of the circuit board 7, and inserted into an opening 7e (a through hole penetrating the circuit board 7 in the thickness direction thereof, as one example in the present embodiment) provided in the circuit board 7. In such a constitution, the arm part 14a1 and the claw part 14a2 of the support 14a are hooked to an edge portion 7h (a support portion, a hook portion) of the opening 7e of the circuit board 7 as an L-shaped crooked hook (a hook portion). The support 14a and the edge portion 7h are engaged with each other thus preventing the side cover 11 and the circuit board 7 from being separated from each other in the direction in which the side cover 11 intersects (intersects at right angle) with the right side 7a of the circuit board 7 and in the direction along the face 7d of the circuit board 7 at the portion on which the support l4a is provided.

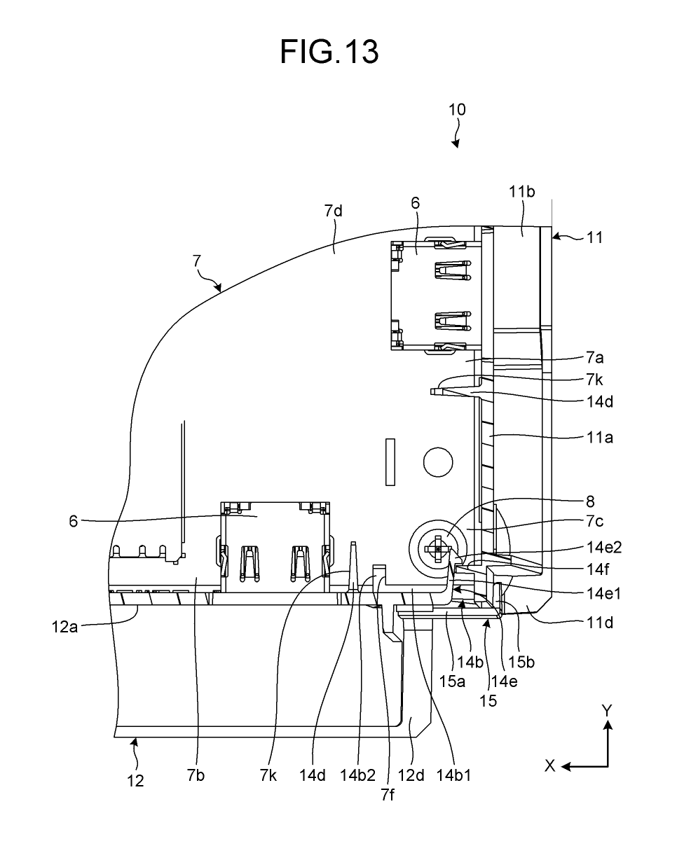

The support 14b is, as illustrated in FIGS. 7 and 8, arranged at a position of the end portion 11d in the longitudinal direction of the side cover 11, and protrudes from the wall portion 11a in the direction intersecting with (orthogonal to) the wall portion 11a. The support 14b extends, as illustrated in FIG. 13, along the bottom side 7b of the circuit board 7. The support 14b comprises an arm part 14b1 and a claw part 14b2. The arm part 14b1 (an extending part, a plate-like part, a strip-like part) extends, as illustrated in FIG. 13, in a strip-like shape (a plate-like shape) from the wall portion 11a along the bottom side 7b in a state where the arm part 14b1 is disposed substantially in contact with the bottom side 7b of the circuit board 7. The claw part 14b2 (a protruding part) protrudes at the distal end portion of the arm part 14b1 in the direction intersecting with (orthogonal to, as one example in the present embodiment) the arm part 14b1 and in the direction along the face 7d of the circuit board 7, and inserted into an opening 7f (a notch provided on the bottom side 7b of the circuit board 7, as one example in the present embodiment) provided in the circuit board 7. In such a constitution, the arm part 14b1 and the claw part 14b2 of the support 14b are hooked to the edge portion 7h (a support portion, a hook portion) of the opening 7f of the circuit board 7 as an L-shaped crooked hook (a hook portion). The support 14b and the edge portion 7h are engaged with each other thus preventing the side cover 11 and the circuit board 7 from being separated from each other in the direction in which the side cover 11 intersects (intersects at right angle) with the right side 7a of the circuit board 7 and in the direction along the face 7d of the circuit board 7 at the portion on which the support 14b is provided. In such a constitution, the support 14b is engaged with the circuit board 7 in a state where the support 14b holds the corner portion 7c of the circuit board 7.

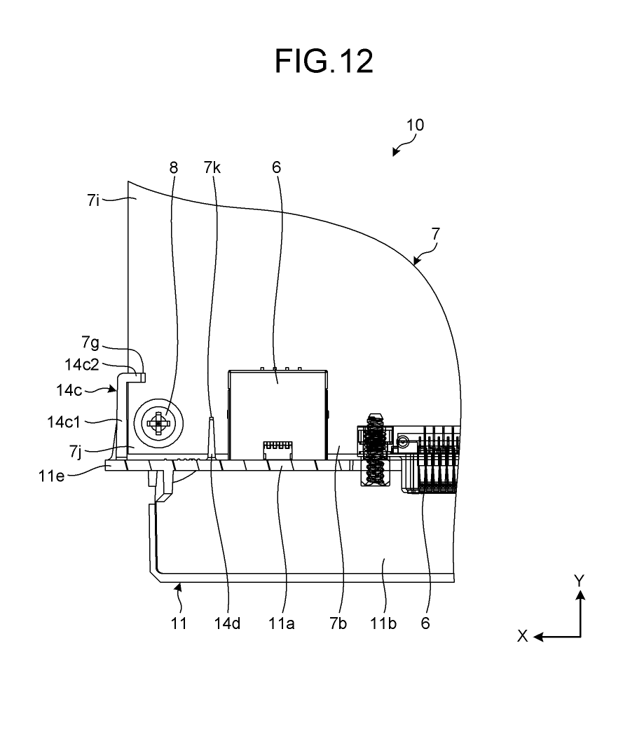

The support 14c is, as illustrated in FIGS. 9 and 10, arranged at a position of an end portion 12e opposite to an end portion 12d in the longitudinal direction of the side cover 12 (the end portion 12d on the side-cover-11 side of the side cover 12), and protrudes from the wall portion 12a in the direction intersecting with (orthogonal to) the wall portion 12a. The support 14c extends, as illustrated in FIG. 12, along a left side 7i of the circuit board 7. The support 14c comprises an arm part 14c1 and a claw part 14c2. The arm part 14c1 (an extending part, a plate-like part, a strip-like part) extends, as illustrated in FIG. 12, in a strip-like shape (a plate-like shape) from the wall portion 11a along the left side 7i in a state where the arm part 14c1 is disposed substantially in contact with the left side 7i of the circuit board 7. The claw part 14c2 (a protruding part) protrudes at the distal end portion of the arm part 14c1 in the direction intersecting with (orthogonal to, as one example in the present embodiment) the arm part 14c1 and in the direction along the face 7d of the circuit board 7, and inserted into an opening 7g (a notch provided on the left side 7i of the circuit board 7, as one example in the present embodiment) provided in the circuit board 7. In such a constitution, the arm. part 14c1 and the claw part 14c2 of the support 14c are hooked to the edge portion 7h (a support portion, a hook portion) of the opening 7g of the circuit board 7 as an L-shaped crooked hook (a hook portion). The support 14c and the edge portion 7h are engaged with each other thus preventing the side cover 11 and the circuit board 7 from being separated from each other in the direction in which the side cover 11 intersects (intersects at right angle) with the bottom side 7b of the circuit board 7 and in the direction along the face 7d of the circuit board 7 at the portion on which the support 14c is provided. In such a constitution, the support 14c is engaged with the circuit board 7 in a state where the support 14c holds a corner portion 7j of the circuit board 7.

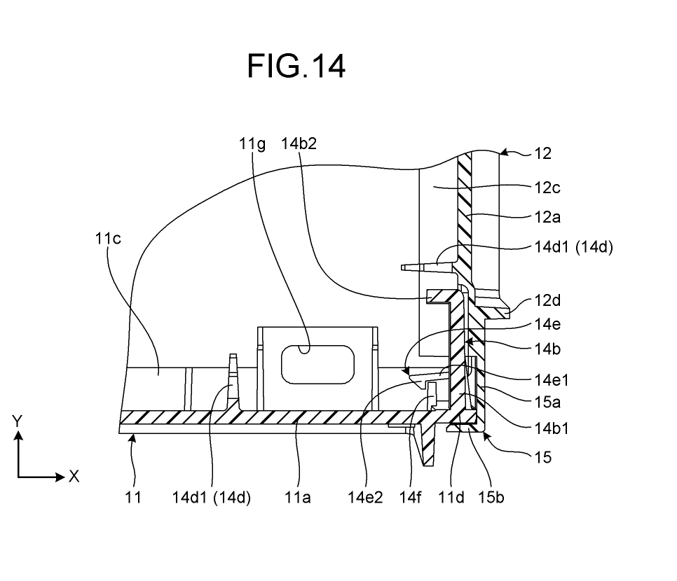

Furthermore, the support 14d is engaged with the circuit board 7 thus preventing the side covers 11 and 12 from being separated from the circuit board 7 in the direction in which the side covers 11 and 12 intersect with the face 7d of the circuit board 7 (in the direction orthogonal to the face 7d of the circuit board 7, in the thickness direction of the circuit board 7) and in the direction along the right side 7a or the bottom side 7b of the circuit board 7. To be more specific, as illustrated in FIGS. 7 and 9, the support 14d is constituted as a wall (a rib) that protrudes from the wall portions 11a and 12a in the direction intersecting with (orthogonal to) the wall portions 11a and 12a and intersecting with (orthogonal to) the face 7d of the circuit board 7. The support 14d is provided with a slit-like opening 14d1 (a notch, see FIG. 14) into which the right side 7a or the bottom side 7b of the circuit board 7 is inserted. Furthermore, the right side 7a and the bottom side 7b of the circuit board 7 are provided with slit-like openings 7k (notches, see FIGS. 11 to 13) into which the support 14d is inserted. That is, in the present embodiment, as one example, the circuit board 7 and the support 14d are arranged in a cross shape (intersected with each other).

Furthermore, in the present embodiment, as one example illustrated in FIGS. 9, 13, and 14, the side cover 12 comprises a support 14e (a second support) supported on the side cover 11. The support 14e comprises an arm part 14e1 and a claw part 14e2. The arm part 14e1 is provided at a position apart from the circuit board 7 and the arm part 14c1 (the support 14c) in the thickness direction of the circuit board 7, comprises a portion (a root portion) extending in a strip-like shape (a plate-like shape) along the bottom side 7b and a portion (a distal end portion) extending in a strip-like shape (a plate-like shape) toward the end portion 11e along the right side 7a at the distal end side thereof, and is constituted in an L shape. The claw part 14e2 protrudes to the wall-portion-11a side of the side cover 11. The side cover 11 comprises a support 14f (a rib) protruding from the wall portion 11a at the wall-portion-12a side of the claw part 14e2 in the direction intersecting with (orthogonal to) the wall portion 11a and intersecting with (orthogonal to) the face 7d of the circuit board 7. In such a constitution, the claw part 14e2 is engaged with the support 14f thus preventing the side cover 12 and the circuit board 7 from being separated from each other in the direction intersecting with (orthogonal to) the bottom side 7b of the circuit board 7 and in the direction along the face 7d of the circuit board 7. In this manner, the constitution in which one of the side cover 11 and the side cover 12 is supported on the other side cover can advantageously be, as one example, adopted when it is difficult to provide a constitution for supporting the side covers 11 and 12 in the circuit board 7 due to problems on the layout of parts in the circuit board 7, or the like. In the present embodiment, as one example, the corner portion 7c of the circuit board 7 is provided with the screw 8. According to the present embodiment, the screw 8 can easily be arranged at a position close to the corner portion 7c of the circuit board 7.

In addition, in the present embodiment, as one example illustrated in FIGS. 9, 13, and 14, the side cover 12 comprises a preventing part 15 for preventing a misalignment between the side cover 11 and the side cover 12. The preventing part 15 comprises an arm portion 15a and a claw portion 15b. The arm portion 15a extends in a strip-like shape (a plate-like shape) along the bottom side 7b on a side opposite to the circuit board 7 in the arm part 14b1 of the support 14b. The claw portion 15b protrudes from the distal end portion of the arm. portion 15a toward the end-portion-11e side of the side cover 11 on a side opposite to the circuit board 7 in the wall portion 11a of the side cover 11. That is, the preventing part 15 covers the support 14b from a side opposite to the circuit board 7. Therefore, according to the present embodiment, as one example, the preventing part 15 prevents the side cover 12 from being spaced apart from the side cover 11 along the bottom side 7b thus preventing a state where the support 14d and the support 14e are engaged with each other (a state where the side cover 12 is supported on the side cover 11) from being released.

In the present embodiment, the side covers 11 and 12 are, in moving to a predetermined support position (a fixing position) with respect to the circuit board 7, at least partially deformed elastically. In the present embodiment, as one example, the supports 14a to 14c, and 14e and the arm portions 14a1, 14b1, 14c1, 14e1, and 15a of the preventing part 15 are, in moving in the same manner as above, deflected elastically and deformed elastically by being pushed by the circuit board 7 or a part of the other member (climbing over the part of the other member). In the present embodiment, these arm portions 14a1, 14b1, 14c1, 14e1, and 15a are one example of a snap-fit mechanism and one example of an elastically deformable member. According to the present embodiment, as one example, time and efforts for assembling (manufacturing) can easily be reduced and a manufacturing cost can easily be reduced compared with the case where a fastener such as a screw or a clip is used. Here, portions other than the arm portions 14a1, 14b1, 14c1, 14e1, and 15a may be elastically deformed. The side covers 11 and 12 are, as one example, made of synthetic-resin materials (plastic, engineering plastic). Furthermore, the side covers 11 and 12 are, as one example, constituted of insulating materials.

Furthermore, in the present embodiment, as one example illustrated in FIG. 15, claw-like support portions 9a are provided on the peripheral edge of the opening 13 of the wall portion 3m of the second member 3Rr of the casing 3. The support portion 9a protrudes into the face 3s (the inner face) of the wall portion 3m, and a gap is formed between the distal end portion of the support portion 9a and the face 3s. A part of the side covers 11 and 12 (peripheral edge portions of openings 11f and 12f (see FIGS. 7 and 9) provided in the wall portions 11c and 12c, as one example in the present embodiment) is inserted into the gap, and the part of the side covers 11 and 12 and the support portion 9a are engaged with each other in the thickness direction of the casing 3. Therefore, according to the present embodiment, as one example, the support portions 9a are inserted into the openings 11f and 12f and hence, the side covers 11 and 12 support the wall portion 3m (the side covers 11 and 12 and the wall portion 3m are engaged with each other). Accordingly, as one example, the wall portion 3m is prevented from being spaced apart from the side covers 11 and 12, the circuit board 7, and in turn the display unit 4 in the thickness direction of the casing 3, and the opening 13 is easily prevented from being stretched in the width direction of the casing. Here, the constitution in which the side covers 11 and 12 and the wall portion 3m are engaged with each other in the thickness direction of the casing 3 is not limited to this example.

In the present embodiment, as one example illustrated in FIG. 15, T-shaped or cross-shaped rib-like support portions 9b are provided on the peripheral edge of the opening 5 of the wall portion 3m of the second member 3Rr of the casing 3. The support portion 9b protrudes into the face 3s of the wall portion 3m, and the distal end portion thereof faces the display unit 4 side. The support portions 9b are inserted into parts of the side covers 11 and 12 (the peripheral edge portions of openings 11g and 12g provided in the wall portions 11c and 12c, as one example in the present embodiment) , and the parts of the side covers 11 and 12 and the support portions 9b are engaged with each other in the direction along the faces 3s and 3b of the wall portion 3m. Therefore, according to the present embodiment, as one example, the support portions 9b are inserted into the openings 11g and 12g and hence, the wall portion 3m supports the side covers 11 and 12 (the side covers 11 and 12 and the wall portion 3m are engaged with each other) . Accordingly, as one example, the side covers 11 and 12 can easily be prevented from being displaced from the wall portion 3m in the direction along the faces 3s and 3b of the wall portion 3m. Here, the constitution in which the side covers 11 and 12 and the wall portion 3m are engaged with each other in the direction along the faces 3s and 3b of the wall portion 3m is not limited to this example.

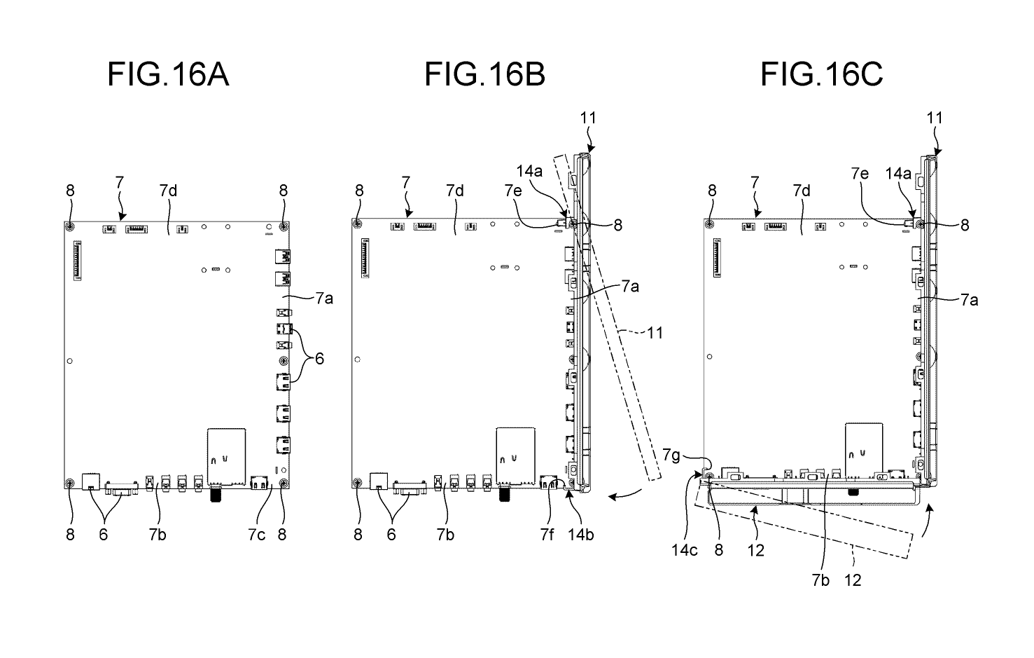

In addition, in the present embodiment, as one example, the side covers 11 and 12 are attached to the circuit board 7 in accordance with the procedures illustrated in FIGS. 16A, 16B, and 16C to constitute the assembly 10. That is, first of all, the side cover 11 is, as illustrated in FIG. 16B, attached to the circuit board 7 in FIG. 16A. In this case, the side cover 11 is, as described above, moved to the fixing position (the support position) on the circuit board 7 while being partially deformed elastically. Furthermore, in this case, as illustrated in FIG. 16B, a worker first hooks one support 14a, as one example, out of two supports 14a and 14b into the opening 7e of the circuit board 7, turns the side cover 11 with the support 14a hooked into the opening 7e as a fulcrum, and can hook the other support 14b into the opening 7f of the circuit board 7. Then, the side cover 12 is, as illustrated in FIG. 16C, attached to the circuit board 7 in FIG. 16B; that is, the circuit board 7 on which the side cover 11 is supported. In this case, the side cover 12 is, as described above, moved to the fixing position (the support position) with respect to the circuit board 7 while being partially deformed elastically. Furthermore, as illustrated in FIG. 16C, the worker first hooks one support 14c, as one example, out of two supports 14c and 14e (see FIGS. 13 and 14) into the opening 7g of the circuit board 7, turns the side cover 12 with the support 14c hooked into the opening 7g as a fulcrum, and can hook the other support 14e into the support 14f (see FIGS. 13 and 14) of the side cover 11.

As explained heretofore, in the present embodiment, as one example, the circuit board 7 supports the side cover 11 covering the right side 7a and the side cover 12 covering the bottom side 7b. Therefore, it is difficult to observe the structure of the circuit board 7 or the like in the casing 3 from the opening 13. Furthermore, as one example, the side covers 11 and 12 can comparatively easily be attached to the circuit board 7 thus reducing easily time and efforts, or a cost for manufacturing the display device. In addition, in the present embodiment, as one example, a worker can move and fix the side covers 11 and 12 to the predetermined position by so-called snap-fit system while partially deforming these side covers thus reducing easily time and efforts, or a cost for manufacturing the display device compared with the case where the side covers 11 and 12 are fixed by using screws or the like.

Furthermore, in the present embodiment, as one example, the side cover 12 comprises the support 14e supported by the side cover 11. Therefore, according to the present embodiment, as one example, it is possible to reduce portions (areas) of the circuit board 7 for supporting the side cover 12. Therefore, as one example, the degree of freedom of the layout of parts on the circuit board 7 is easily increased.

Furthermore, in the present embodiment, as one example, the side cover 12 comprises the preventing part 15 for preventing the misalignment with respect to the side cover 11. Therefore, according to the present embodiment, as one example, in the constitution in which the side cover 12 is supported by the side cover 11, a state where the side cover 12 is supported by the side cover 11 is easily prevented from being released.

In addition, in the present embodiment, as one example, the width w2 (height) of the support 14e is narrower than the widths w1 (heights) of the side covers 11 and 12. Therefore, according to the present embodiment, as one example, the support 14e is easily deformed elastically, and an operation for engaging the side cover 12 with the side cover 11 is easily performed.

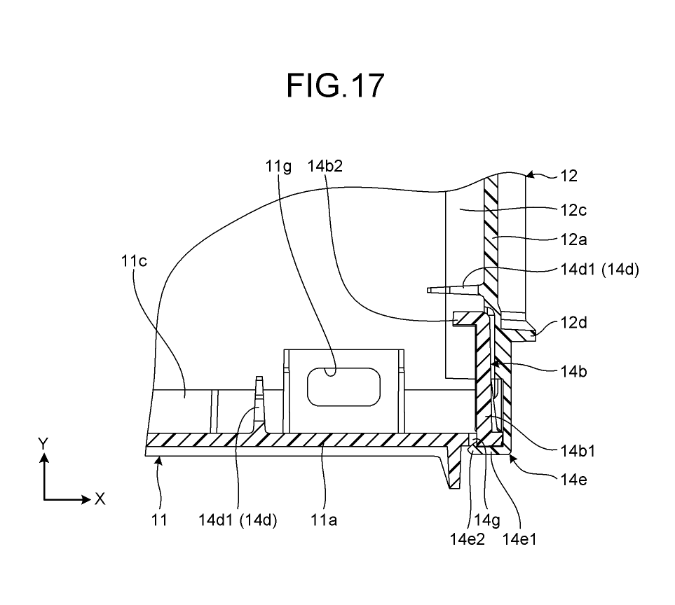

Furthermore, the technical features of the above mentioned embodiments and modifications can be realized by combining those properly or by replacing those partially. Furthermore, the specifications (structures, types, directions, shapes, sizes, lengths, widths, thicknesses, heights, numbers, arrangements, positions, materials, or the like) of the respective constitutions (locations, features) can be also realized after being changed as appropriate. For example, in the above-mentioned embodiments and modifications, a constitution (locations, features) that one side cover comprises can be comprised by the other side cover or by both side covers also. The constitution in which the side covers are engaged with each other or the side cover and the circuit board are engaged with each other can variously be modified. For example, as the modification illustrated in FIG. 17, the constitution in which the support 14e of the side cover 12 holds the side cover 11 may be adopted. In this case, the claw portion 14e2 of the support 14e may be inserted into a opening 14g provided in the side cover 11.

Moreover, the various modules of the systems described herein can be implemented as software applications, hardware and/or software modules, or components on one or more computers, such as servers. While the various modules are illustrated separately, they may share some or all of the same underlying logic or code.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device comprising:
a casing comprising an opening;
a display, at least a part of the display being housed in the casing;
a circuit board configured to be housed in the casing and comprising a first side and a second side;
a plurality of connector terminals on each of the first side and the second side of the circuit board and exposed through the opening;
a first covering configured to be supported on the circuit board, and facing the first side to cover the opening; and
a second covering configured to be supported on the circuit board, and facing the second side to cover the opening.

2. The display device of claim 1, wherein each of the first covering and the second covering comprises a second opening exposing the connector terminal.

3. The display device of claim 1, wherein at least one of the first covering and the second covering comprises a plurality of first supports supported on the circuit board.

4. The display device of claim 1, wherein at least one of the first covering and the second covering comprises a second support supported on the other of the first covering and the second covering.

5. The display device of claim 4, wherein at least one of the first covering and the second covering comprises a preventing part preventing misalignment between the first covering and the second covering.

6. The display device of claim 4, wherein a width of the second support is smaller than a width of the first covering and a width of the second covering.

7. The display device of claim 1, wherein at least one of the first covering and the second covering comprises an elastically deformable member elastically deformed while being moved to a position where the at least one of the first covering and the second covering is supported on the circuit board.

8. The display device of claim 1, wherein at least one of the first covering and the second covering is made of a synthetic-resin material.

9. The display device of claim 1, wherein the casing comprises a wall portion covering a side of the circuit board, the side being opposite to the display, and at least one of the first covering and the second covering is configured to support the wall portion.

10. A display device comprising:
a casing comprising an opening;
a display, at least a part of the display being housed in the casing;
a circuit board configured to be housed in the casing and comprising a side;
a plurality of connector terminals on the side of the circuit board and exposed through the opening;
a covering configured to be supported on the circuit board, facing the side to cover the opening, and comprising an elastically deformable member elastically deformed while being moved to a position where the covering is supported on the circuit board; and
a wall portion configured to constitute a part of the casing, covering a side of the circuit board, the side being opposite to the display, and covering at least a part of the covering.
